(19) United States
(12) Patent Application Publication
(10) Pub. No.: US 2025/0353126 A1
(43) Pub. Date: Nov. 20, 2025

(54) BALANCE STAGE

(71) Applicant: BLUEROBOT, Sejong (KR)

(72) Inventor: Sae Hwan HYUN, Cheonan-si, Chungcheongnam-do (KR)

(73) Assignee: BLUEROBOT, Sejong (KR)

(21) Appl. No.: 18/709,018

(22) PCT Filed: Sep. 16, 2022
(86) PCT No.: PCT/KR2022/013859

§ 371 Date: Sep. 27, 2024

(30) Foreign Application Priority Data
Jan. 4, 2022 (KR) 10-2022-0000916

(51) Int. Cl. B23Q 3/00

(52) U.S. Cl. CPC B23Q 3/00

(57) ABSTRACT

Disclosed is a balance stage. According to the present invention, provided is a balance stage including: a lower base disposed on an installation surface; an inner rail extended in a circumferential direction, and supported on the lower base to be rotatable with respect to the lower base around a central axis in the circumferential direction; an outer rail extended in the circumferential direction, and supported on the inner rail to be rotatable with respect to the inner rail around the central axis; an upper base 140 which is supported on the outer rail, and in which an object is disposed; and a rotation support part fastened between the lower base and the upper base, and restraining rotation of the upper base with respect to the lower base. Sine the present invention is implemented in a comparative simple structure, can precisely control an angle, and has a stable weight support structure, the present invention can be used in various objects.

### TECHNICAL FIELD

The present invention relates to a balance stage used to adjust the inclination or balance of an object.

### BACKGROUND ART

As a means for controlling a posture of an object or adjusting a balance of the object, a balance stage is used in various industrial fields. As an example, a balance stage for tilting a substrate based on each axis according to a working process can be used in a semiconductor manufacturing process. Further, various types of balance stages are developed and used in a manufacturing or test field which handles various precise parts in addition to a semiconductor industry.

For reference, the balance stage can also be referred to as an equilibrium stage and a tilting stage. For convenience, in this specification, the stages are collectively called the balance stage.

As one of the balance stages known in the related art, “a precise driving tilt stage” of Korean Patent Unexamined Publication No. 10-2020-0113866 proposes a configuration which can be simply operated and can reduce backlash by using a scheme in which an upper stage is swung. As another example, “a tilting stage system” of Korean Patent Unexamined Publication No. 10-2018-0023739 proposes a configuration which can adjust a balance of a stage in a simple structure by applying actuation force to an eccentric area of the stage. As yet another example, “a tilt stage apparatus” of Korean Patent Registration No. 10-1732851 proposes a configuration which enables multi-axis rotations of the stage by combining a rotation motion of a rotatable part and a vertical motion of a movable part.

A more general form of the balance stage is a scheme which adds a plurality of actuators to the stage to tilt the stage according to actuation of each actuator. However, in such a scheme, multiple actuators are required, so a price is high, and precise control of each actuator is not also easy. In particular, when handling an object with a large weight, more actuators are required in proportion to the weight, and more precise control is required for the evenly distribution of weight.

In this background, a variety of modified balance stages as mentioned above have been proposed, but they are also made of quite complex structures and a number of precise parts, making it difficult to manufacture, and actually handle or operate. Further, most simplified type of balance stages are limited in terms of precise angle control, so the balance stages can be limited in terms of use ranges thereof.

Therefore, even though various types of balance stages have been developed and used to date, the demand for more improved balance stages continues.

### DISCLOSURE

### Technical Problem

Embodiments of the present invention have been made in an effort to provide a balance stage which can be implemented in a comparative simple structure to achieve an advantage in terms of manufacturing or handling.

Further, the embodiments of the present invention have been made in an effort to provide a balance stage which can precisely and stably control an angle in spite of a simple structure.

Further, the embodiments of the present invention have been made in an effort to provide a balance stage which has a stable weight support structure to be used appropriately to an object with a large weight, and has excellent durability and can reduce malfunction.

However, the technical objects to be achieved by the present invention are not particularly limited to the above-mentioned technical objects. Other technical objects that are not mentioned can be clearly understood by those skilled in the art to the embodiments of the present invention pertain from other descriptions io the specification, such as Detailed Description, etc.

### Technical Solution

According to an aspect of the present invention, a balance stage can be provided, which includes: a lower base disposed on an installation surface; an inner rail extended in a circumferential direction, and supported on the lower base to be rotatable with respect to the lower base around a central axis in the circumferential direction; an outer rail extended in the circumferential direction, and supported on the inner rail to be rotatable with respect to the inner rail around the central axis; an upper base 140 which is supported on the outer rail, and in which an object is disposed; and a rotation support part fastened between the lower base and the upper base, and restraining rotation of the upper base with respect to the lower base.

### Advantageous Effects

The balance stage according to the embodiments of the present invention can adjust a tilting direction or angle of an object, and implement an tilting operation through rotation of an inner rail or an outer rail.

Here, the balance stage according to the embodiments of the present invention has a structure in which the tilting direction or angle is adjusted through tilting of the inner rail or outer rail, and a rotation position of the inner rail or outer rail, a simple structure is provided and precise angle control is possible compared to the related art. Further, there is an advantage in that manufacturing or handling is easy according to a simple or intuitive structure.

Further, the balance stage according to the embodiments of the present invention has a structure in which the inner rail, the outer rail, and an upper base are supported throughout an entire area in a circumferential direction based on a lower base. Accordingly, the balance stage can have a very stable weight support structure, and can be appropriately used even with respect to an object with a large weight. Furthermore, durability is excellent according to the stable weight support structure, and malfunction can also be significantly reduced.

However, the technical effects that can be obtained through the embodiments of the present invention are not necessarily limited to the effects mentioned above. Other technical effects that are not mentioned can be clearly understood by those skilled in the art to the present invention pertains from other descriptions of the specification, such as Detailed Description, etc.

### DESCRIPTION OF DRAWINGS

FIG. 1 is a schematic perspective view of a balance stage according to an embodiment of the present invention.

FIG. 2 is a schematic perspective view of the balance stage illustrated in FIG. 1, which is viewed in another direction.

FIG. 3 is a schematic exploded perspective view of the balance stage illustrated in FIG. 1.

FIG. 4 is a schematic longitudinal cross-sectional view of the balance stage taken along line A1-A1 marked in FIG. 2.

FIG. 5 is a schematic transverse cross-sectional view of the balance stage taken along line A2-A2 marked in FIG. 4.

FIG. 6 is a schematic transverse cross-sectional view of the balance stage taken along line A3-A3 marked in FIG. 4.

FIG. 7 is a schematic transverse cross-sectional view of the balance stage taken along line A4-A4 marked in FIG. 4.

FIG. 8 is a schematic longitudinal cross-sectional view separately illustrating a lower base illustrated in FIG. 4.

FIG. 9 is a schematic longitudinal cross-sectional view separately illustrating an inner rail illustrated in FIG. 4.

FIG. 10 is a schematic longitudinal cross-sectional view separately illustrating an outer rail illustrated in FIG. 4.

FIG. 11 is a schematic longitudinal cross-sectional view separately illustrating an upper base illustrated in FIG. 4.

FIG. 12 is a schematic perspective view separately illustrating a rotation support part illustrated in FIG. 4.

FIG. 13 is a schematic perspective view illustrating another embodiment of a rotation support part illustrated in FIG. 12.

FIG. 14 is an operation diagram of the balance stage illustrated in FIG. 4.

### MODE FOR INVENTION

Hereinafter, embodiments of the present invention will be described with reference to the accompanying drawings. The following embodiments can be provided for more completely explaining the present invention to those skilled in the art. However, the following embodiments are provided to help understanding the present invention, and the technical ideas of the present invention are not particularly limited to the following embodiments. In addition, detailed descriptions will be omitted for a configuration which makes the technical gist of the present invention unclear or is known.

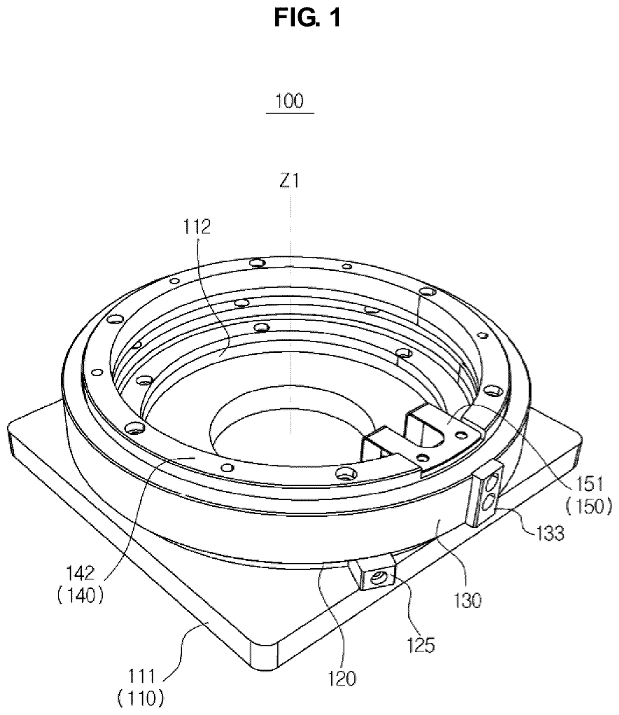

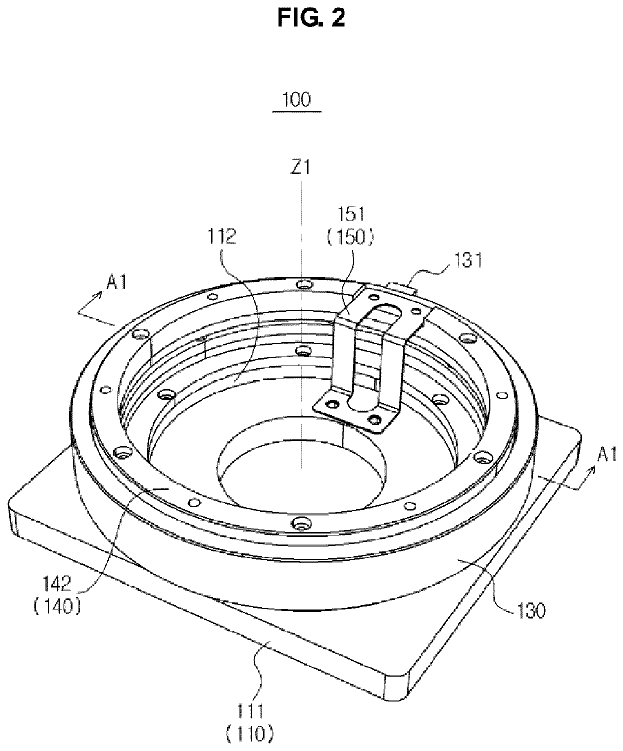

FIG. 1 is a schematic perspective view of a balance stage according to an embodiment of the present invention. FIG. 2 is a schematic perspective view of the balance stage illustrated in FIG. 1, which is viewed in another direction.

Referring to FIGS. 1 and 2, the balance stage 100 may include a lower base 110.

The lower base 110 may be disposed at a lower end of the balance stage 100. The lower base 110 may provide a reference support point for an upper base 140 to be described below. That is, the lower base 110 may be fixed onto a predetermined installation surface, and the upper base 140 is relatively tilted with respect to the lower base 110, so a tilting operation for the object may be implemented.

The lower base 110 may include a lower plate 111. In the exemplary embodiment, the lower plate 111 is exemplified as a plate type having a predetermined plane area. However, a shape of the lower plate 111 is not particularly limited to an exemplified shape. That is, the lower plate 111 may be formed with various structures or shapes for appropriately fixing the balance stage 100 on the installation surface. Further, in this specification, for convenience of understanding, the lower plate is referred to as “lower plate 111”, but the lower plate 111 is not particularly limited to a plate type like the name, and may include various types of frames, brackets, coupling components, etc. which may provide the same or similar function.

Meanwhile, the balance stage 100 may include an inner rail 120.

The inner rail 120 may be disposed on an upper surface portion of the lower plate 111, and supported by the lower base 110. The inner rail 120 may be formed rotatably with respect to the lower base 110. That is, the inner rail 120 may be formed rotatably based on an upper and lower-direction central axis Z1 of the balance stage 100. The balance stage 100 implement the tilting operation by combining rotation of the inner rail 120 and rotation of an outer rail 130 to be described below.

Actuation is, by a predetermined actuation means, applied to the inner rail 120, which may be rotated and manipulated. In the embodiment, a case where a first actuation block 125 is provided at one side of a lateral surface of the inner rail 120. In such a case, the actuation means such as an actuator, a motor, etc. applies the actuation force to the first actuation block 125, so the inner rail 120 may be appropriately rotated based on the central axis Z1.

Meanwhile, the balance stage 100 of the embodiment may include the outer rail 130.

The outer rail 130 may be disposed on the top of the inner rail 120. Further, the outer rail 130 may be disposed on an outer periphery of the inner rail 120. The outer rail 130 may be supported by the inner rail 120 on the top of the inner rail 120. Further, the outer rail 130 may be formed rotatably with respect to the inner rail 120. That is, similar to the inner rail 120 described above, the outer rail 130 may be formed rotatably based on the central axis Z1. As the inner rail 120 and the outer rail 130 rotate to predetermined positions, respectively, the balance stage 100 may be appropriately tilted at corresponding angles. This will be described below.

Similar to the inner rail 120, the actuation force is, by a predetermined actuation means, applied to the outer rail 130, which may be rotated and manipulated. In the embodiment, a case where a second actuation block 133 is provided at one side of a lateral surface of the outer rail 130. The actuation means such as the actuator, the motor, etc. applies the actuation force to the second actuation block 133, so the outer rail 130 may be appropriately rotated based on the central axis Z1.

In the above description, each of the inner rail 120 and the outer rail 130 may be independently rotated. That is, a rotation position or direction of the inner rail 120 may be set independently from the rotation position or direction of the outer rail 130. Accordingly, the actuation means that applies a rotation driving force to the inner rail 120 through the first actuation block 125 and the actuation means that applies to the rotation driving force to the outer rail 130 through the second actuation block may be each separately provided, or formed to operate mutually independently.

Meanwhile, the balance stage 100 of the embodiment may include the upper base 140.

The upper base 140 may be disposed on the top of the outer rail 130 and supported by the outer rail 130. The upper base 140 corresponds to the lower base 110 to form an upper structure of the balance stage 100. The object may be seated and disposed on the upper base 140. The upper base 140 may be tilting-operated with respect to the lower base 110 by the inner rail 120 and the outer rail 130. Therefore, tilting for the object disposed in the upper base 140 may be implemented.

The upper base 140 may include an upper rail 142 and an upper plate. For reference, in FIG. 1, etc., for illustration convenience, the upper plate is omitted. The upper plate may have an appropriate structure or shape to support the object, and the structure or shape is not particularly limited. As an example, the upper plate may have a plate type having a predetermined plane area similar to the lower plate 111.

The upper rail 142 may be provided on the bottom of the upper plate. The upper rail 142 may be fastened to an inner periphery portion of the outer rail 130, and supported by the outer rail 130. As a result, a placement state of the upper rail 142 or the upper base 140 may be appropriately adjusted according to postures of the inner rail 120 and the outer rail 130.

Meanwhile, the balance stage 100 of the embodiment may include a rotation support part 150.

The rotation support part 150 may be fastened between the lower base 110 and the upper base 140. That is, one side (lower end) of the rotation support part 150 may be fastened to the lower bass 110, and the other side (upper end) may be fastened to the upper base 140.

The rotation support part 150 may restrain the upper base 140 from rotating with respect to the lower base 110. That is, the rotation support part 150 may restrain the rotation of the upper base 140 around the central axis Z1. As a result, the upper base 140 may not be rotated jointly with the inner rail 120 or the outer rail 130, but only the placement posture may be changed at a predetermined rotation position. That is, the upper base 140 may not be rotated jointly with the inner rail 120 and the outer rail 130, but may be tilting-operated at a predetermined rotation position.

The rotation support part 150 may be formed to allow tilting of the upper base 140. That is, the rotation support part 150 may restrain the rotation of the upper base 140 with respect to the central axis Z1, and allow the tilting of the upper base 140 with respect to an arbitrary axis on a plane.

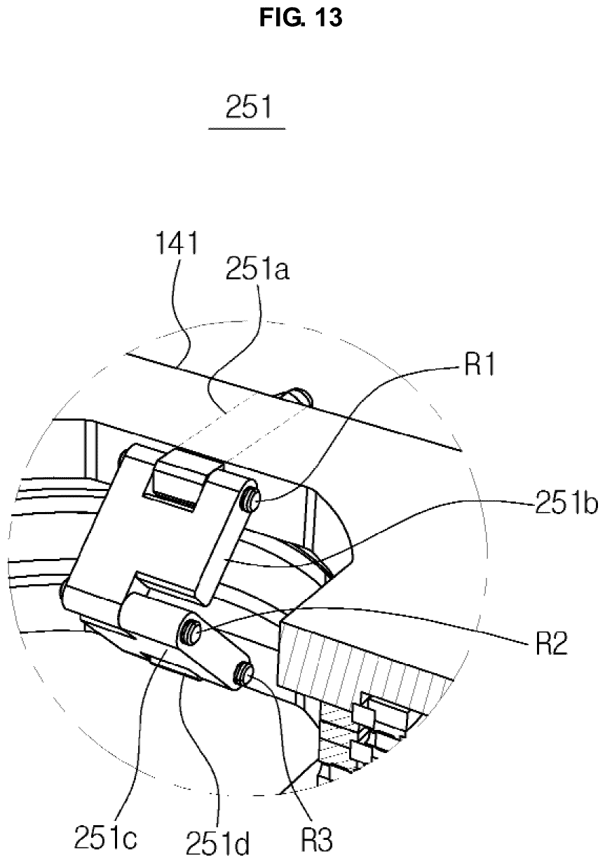

The rotation support part 150 may be implemented as various types. In the embodiment, a case where the rotation support part 150 is implemented as an elastic clip 151 is exemplified. As a result, hereinafter, a case where the rotation support part 150 is implemented as the elastic clip 151 will be primarily described. For reference, FIG. 13 illustrates another embodiment of the rotation support part 150.

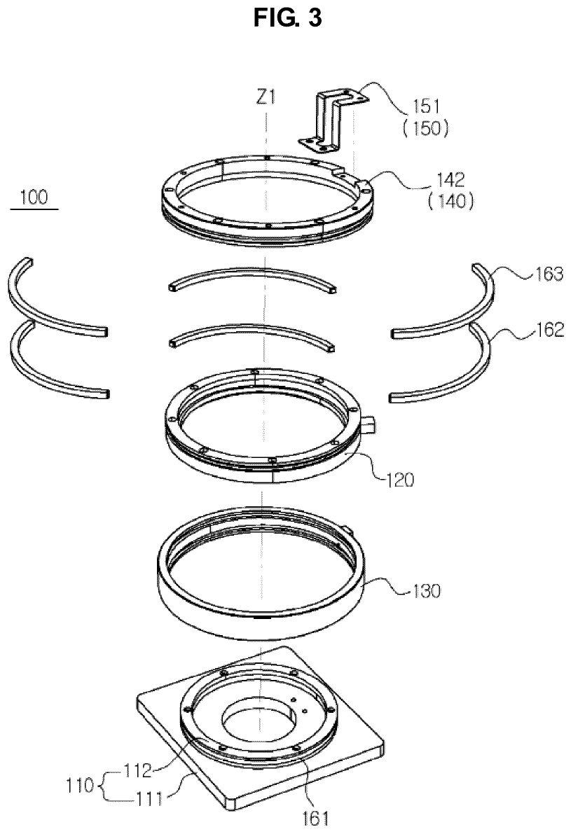

FIG. 3 is a schematic exploded perspective view of the balance stage illustrated in FIG. 1.

Referring to FIG. 3, a first bearing 161 may be provided between the lower base 110 and the inner rail 120. The first bearing 161 may rotatably support the inner rail 120 with respect to the lower base 110.

Meanwhile, a second bearing 162 may be provided between the inner rail 120 and the outer rail 130. The second bearing 162 may rotatably support the outer rail 130 with respect to the inner rail 120.

The second bearing 162 may be split into a plurality of second bearings as necessary. In the embodiment, a case where the second bearing 162 is split into three is exemplified. However, the present disclosure is not limited thereto.

Meanwhile, a third bearing 163 may be provided between the outer rail 130 and the upper base 140. The third bearing 163 may rotatably support the outer rail 130 with respect to the upper base 140.

Similar to the second bearing 162, the third bearing 163 may be split into a plurality of third bearings as necessary. In the embodiment, a case where the third bearing 163 is split into three is exemplified.

Meanwhile, the lower rail 1112, the inner rail 120, the outer rail 130, and the upper rail 142 may share the central axis Z1. Further, each of the lower rail 112, the inner rail 120, the outer rail 130, and the upper rail 142 may be formed in a circular ring form around the central axis Z1.

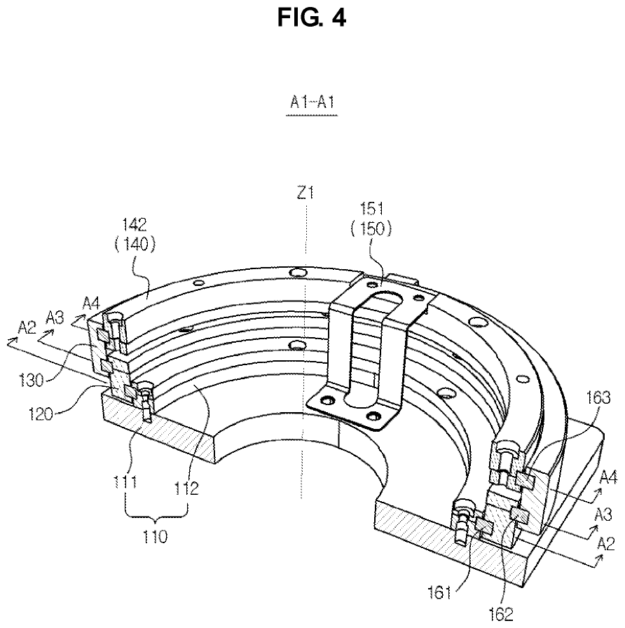

FIG. 4 is a schematic longitudinal cross-sectional view of the balance stage taken along line A1-A1 marked in FIG. 2.

Referring to FIG. 4, the lower base 110 may be disposed at the lower end of the balance stage 100. The inner rail 120 may be fastened to the lower rail 112 via the first bearing 161 on the top of the lower base 110. The inner rail 120 may be fastened to an outer periphery portion of the lower rail 112, and rotated with respect to the lower rail 112 through the first bearing 161.

The outer rail 130 may be fastened to the inner rail 120 via the second bearing 162 on the top of the inner rail 120. The outer rail 130 may be fastened to an outer periphery portion of the inner rail 120, and rotated with respect to the inner rail 120 through the second bearing 162.

The upper rail 142 may be fastened to the outer rail 130 via the third bearing 163 on the top of the outer rail 130. The upper rail 142 may be fastened to an inner periphery portion of the outer rail 130, and rotatably fastened to the outer rail 130 through the third bearing 163. However, since the rotation of the upper rail 142 is restrained by the elastic clip 151, the outer rail 130 may be substantially rotated with respect to the upper rail 142. The upper plate is provided on the top of the upper rail 142 to form the upper base 140.

Overall, a structure may be provided, in which rotation of the lower base 110 at the lower end and the upper base 140 at the upper end may be restrained, and the inner rail 120 and the outer rail 130 disposed between the lower base 110 and the upper base 140 are rotated around the central axis Z1.

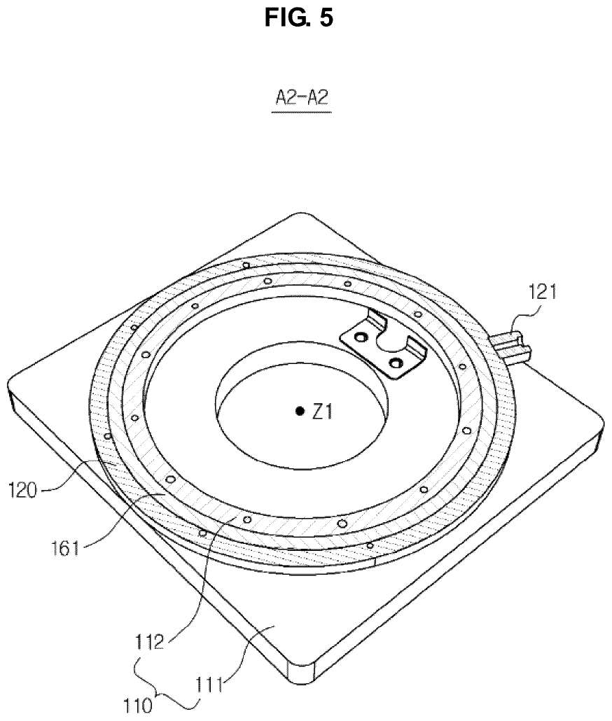

FIG. 5 is a schematic transverse cross-sectional view of the balance stage taken along line A2-A2 marked in FIG. 4.

Referring to FIG. 5, each of the lower rail 112, the first bearing 161, and the inner rail 120 may be extended while forming a circular trajectory on the plane. The lower rail 112 may be disposed inside a radial direction with a relatively small radius, and the inner rail 120 may be disposed outside the radial direction with a relatively large radius. The first bearing 161 may be disposed between the lower rail 112 and the inner rail 120. When a predetermined actuation force is applied to the first actuation block 125, the inner rail 120 may be rotated with respect the lower rail 112 with the first bearing 161 interposed therebetween.

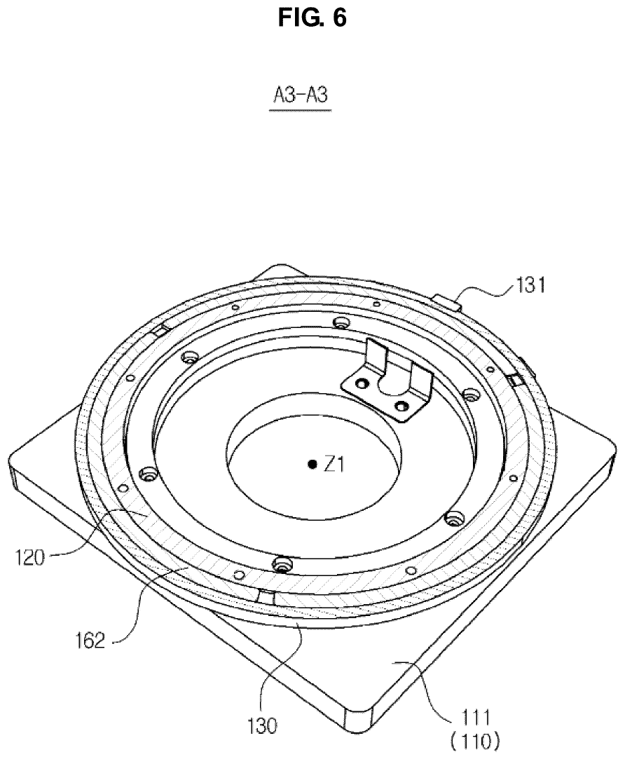

FIG. 6 is a schematic transverse cross-sectional view of the balance stage taken along line A3-A3 marked in FIG. 4.

Referring to FIG. 6, each of the inner rail 120, the second bearing 162, and the outer rail 130 may be extended while forming the circular trajectory on the plane on the top of the FIG. 5. The outer rail 130 may be disposed outside the radial direction with a relatively larger radius than the inner rail 120, and the second bearing 162 may be disposed between the inner rail 120 and the outer rail 130. When a predetermined actuation force is applied to the second actuation block 133, the outer rail 120 may be rotated with respect the inner rail 120 with the second bearing 162 interposed therebetween.

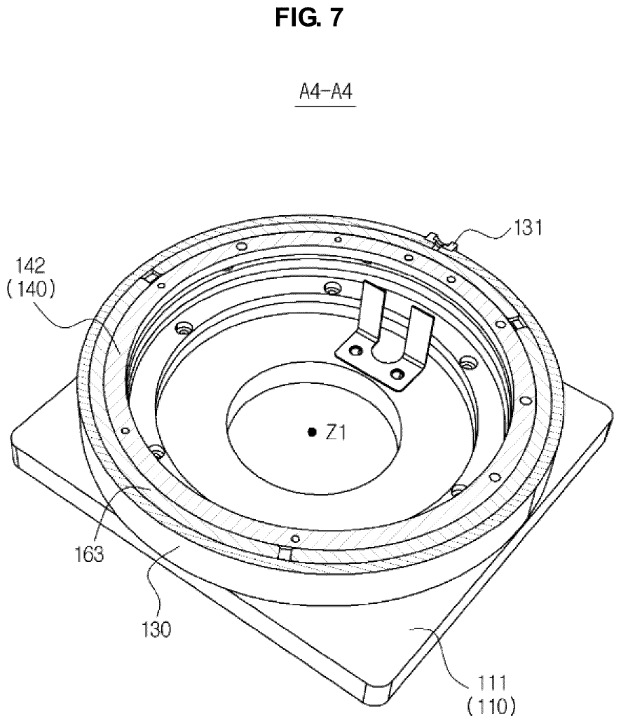

FIG. 7 is a schematic transverse cross-sectional view of the balance stage taken along line A4-A4 marked in FIG. 4.

Referring to FIG. 7, each of the upper rail 142, the third bearing 163, and the outer rail 130 may be extended while forming the circular trajectory on the plane on the top of the FIG. 6. The upper rail 142 may be disposed outside the radial direction with a relatively smaller radius than the outer rail 130, and the third bearing 163 may be disposed between the upper rail 142 and the outer rail 130. The elastic clip 142 is fastened between the upper rail 142 and the lower plate 111, so the rotation of the upper rail 142 may be restrained.

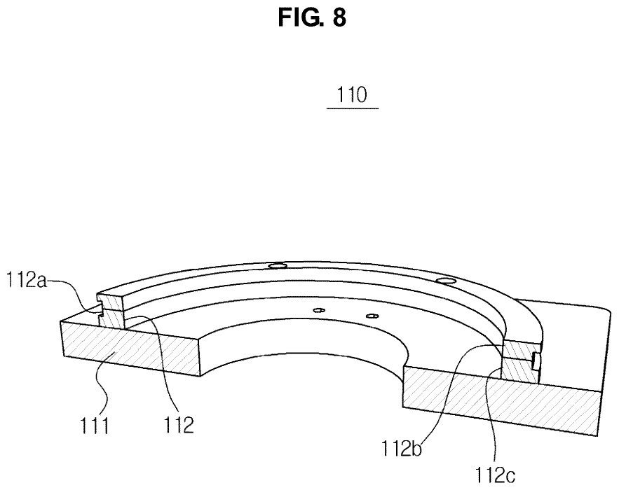

FIG. 8 is a schematic longitudinal cross-sectional view separately illustrating a lower base illustrated in FIG. 4.

Referring to FIG. 8, the lower base 110 may include the lower plate 111. As described above, in the embodiment, the lower plate 111 is exemplified as a plate type having a predetermined plane area.

The lower base 110 may include the lower rail 112. The lower rail 112 may be extended in a circular shape with a predetermined radius. Further, the lower rail 112 may be disposed on an upper surface of the lower plate 111, and may be fixed to the lower plate 111, and restrained from being rotated. That is, the inner rail 120 and the outer rail 130 to be described below are possible to rotate around the central axis Z1, while the lower rail 112 is fixed to the lower plate 111 or integrally formed in the lower plate 111 to be restrained from being rotated.

The lower rail 112 may be split into a plurality of lower rails as necessary. In the embodiment, a case where the lower rail 112 is split into a lower rail lower block 112c and a lower rail upper block 112b is exemplified. The lower rail lower block 112c and the lower rail upper block 112b are stacked and assembled vertically to form the lower rail 112.

The lower rail 112 may be extended in the circular shape with a predetermined radius. As a result, the lower rail 112 may have a radial inner surface facing the central axis Z1 and a radial outer surface which is an opposite thereto.

Further, the lower rail 112 may include a 1-1^{st} bearing groove 123. The 1-1^{st} bearing groove 123 may be extended along the radial outer surface of the lower rail 112. When the lower rail 112 is split into the lower rail upper block 112b and the lower rail lower block 112c, a part of a 1-1^{st} bearing groove 123 formed in the lower rail lower block 112c and the remaining part of the 1-1^{st} bearing groove 123 formed in the lower rail upper block 112b are combined to form the 1-1^{st} bearing groove 123. The 1-1^{st} bearing groove 123 is combined with a 1-2^{nd} bearing groove 121c to be described below to mount and support the first bearing 161.

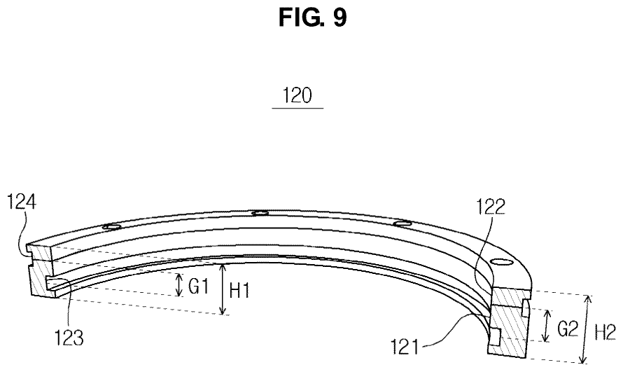

FIG. 9 is a schematic longitudinal cross-sectional view separately illustrating an inner rail illustrated in FIG. 4.

Referring to FIG. 9, the inner rail 120 may be extended in the circular shape with a predetermined radius. Similar to the lower rail 112, the inner rail 120 may have a radial inner surface facing the central axis Z1 and a radial outer surface which is an opposite thereto.

The inner rail 120 may be split into a plurality of inner rails as necessary. In the embodiment, a case where the inner rail 120 is split into an inner rail lower block 121 and an inner rail upper block 122 is exemplified. The inner rail lower block 121 and the inner rail upper block 122 are stacked and assembled vertically to form the inner rail 120.

The inner rail 120 may include a 1-2^{nd} bearing groove 121c. The 1-2^{nd} bearing groove 121c may be disposed adjacent to the lower end of the inner rail 120, and extended along the radial inner surface of the inner rail 120. The 1-2^{nd} bearing groove 121c is combined with the 1-1^{st} bearing groove 123 to mount and support the first bearing 161.

According to the above description, the inner rail 120 may be supported on the lower rail 112. That is, the first bearing 161 is fastened to the 1-1^{st} bearing groove 123 formed in the lower rail 112, and the 1-2^{nd} bearing groove 121c formed in the inner rail 120 is fastened to the first bearing 161 again, so the inner rail 120 may be supported on the lower rail 112 via the first bearing 161. Further, the inner rail 120 may be rotated with respect to the lower rail 112 via the first bearing 161.

Further, the inner rail 120 may include a 2-1^{st} bearing groove 124. The 2-1^{st} bearing groove 124 may be disposed adjacent to the upper end of the inner rail 124, and extended along the radial outer surface of the inner rail 120. The 2-1^{st} bearing groove 124 is combined with a 2-2^{nd} bearing groove 131 to be described below to mount and support the second bearing 162.

Meanwhile, a longitudinal height of the inner rail 120 may be formed differently according to a circumferential position. Specifically, the inner rail 120 may have a first height H1 in a longitudinal direction at one side (a left side in the drawing), and may have a second height H2 in the longitudinal direction at the other side (a right side in the drawing) spaced apart therefrom by a predetermined interval in the circumferential direction. Here, the second height H2 may be larger than the first height H1 by a predetermined degree. Further, the inner rail 120 may be formed with a height of the inner rail 120 gradually increases or decreases in the circumferential direction. That is, when it is assumed that the first height H1 is a minimum height of the inner rail 120 and the second height H2 is a maximum height of the inner rail 120, the height of the inner rail 120 may gradually increase from the position of the second height H2 to the position of the second height H2 in the circumferential direction. Further, the height of the inner rail 120 may gradually decrease in the circumferential direction from the position of the second height H2 to the position of the first height H1.

When the 1-2^{nd} bearing groove 121c is disposed at a position spaced apart from the lower end of the inner rail 120 by a predetermined interval, and the 2-1^{st} bearing groove 124 is disposed at a position spaced apart from the upper end of the inner rail 120 by a predetermined interval, an interval between the 1-2^{nd} bearing groove 121c and the 2-1^{st} bearing groove 124 may also be changed according to the position by such a height change of the inner rail 120. That is, an internal between the 1-2^{nd} bearing groove 121c and the 2-1^{st} bearing groove 124 may be formed differently according to each circumferential position of the inner rail 120. The balance stage 100 of the embodiment may implement the tilting operation through such a difference of the interval (height).

When the concept is differently described, the 1-2^{nd} bearing groove 121c and the 2-1^{st} bearing groove 124 may be vertically spaced apart from each other by a first interval G1 at one side (the left side in the drawing) of the inner rail 120, and the 1-2^{nd} bearing groove 121c and the 2-1^{st} bearing groove 124 may be vertically spaced apart from each other by a second interval G2 at the other side (the right side in the drawing) of the inner rail 120. The first interval G1 and the second interval G2 may be defined as an interval between an upper and lower-direction center of the 1-2^{nd} bearing groove 121c and an upper and lower-direction center of the 2-1^{st} bearing groove 124. Here, similar thereto, the second interval G2 may be formed to be larger than the first interval G1 by a predetermined degree. Further, the interval between the 1-2^{nd} bearing groove 121c and the 2-1^{st} bearing groove 124 may gradually increase in the circumferential direction from the position of the first interval G1 to the position of the second interval G2, and in contrast, the interval between the 1-2^{nd} bearing groove 121c and the 2-1^{st} bearing groove 124 may gradually decrease in the circumferential direction from the position of the second interval G2 to the position of the first interval G1.

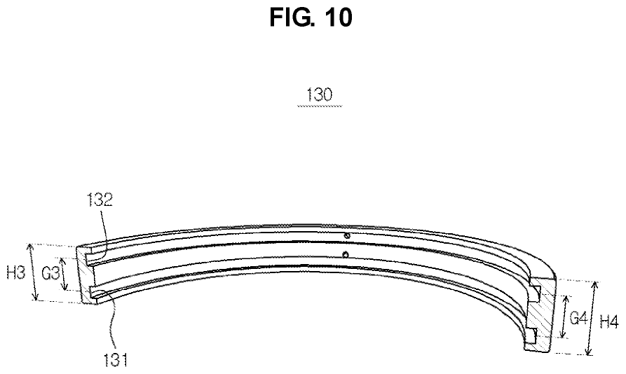

FIG. 10 is a schematic longitudinal cross-sectional view separately illustrating an outer rail illustrated in FIG. 4.

Referring to FIG. 10, the outer rail 130 may be extended in the circular shape with a predetermined radius. Similar to the inner rail 112, the outer rail 120 may have a radial inner surface facing the central axis Z1 and a radial outer surface which is an opposite thereto.

The outer rail 130 may include a 2-2^{nd} bearing groove 131. The 2-2^{nd} bearing groove 131 may be disposed adjacent to the lower end of the outer rail 130, and extended along the radial inner surface of the outer rail 130. The 2-2^{nd} bearing groove 131 is combined with a 2-1^{st} bearing groove 124 to mount and support the second bearing 162.

According to the above description, the outer rail 130 may be supported on the inner rail 120. That is, the second bearing 162 is fastened to the 2-1^{st} bearing groove 124 formed in the inner rail 120, and the 2-2^{nd} bearing groove 131 formed in the outer rail 130 is fastened to the second bearing 162 again, so the outer rail 130 may be supported on the inner rail 120 via the second bearing 162. Further, the outer rail 130 may be rotated with respect to the inner rail 120 via the second bearing 162.

Further, the outer rail 130 may include a 3-1^{st} bearing groove 132. The 3-1^{st} bearing groove 132 may be disposed adjacent to the upper end of the outer rail 130, and extended along the radial inner surface of the outer rail 130. The 3-1^{st} bearing groove 132 is combined with a 3-2^{nd} bearing groove 121c to be described below to mount and support the third bearing 163.

Similar to the inner rail 120, a longitudinal height of the outer rail 130 may also be formed differently according to the circumferential position. Specifically, the outer rail 130 may have a third height H3 in the longitudinal direction at one side (the left side in the drawing), and may have a fourth height H4 in the longitudinal direction at the other side (the right side in the drawing) spaced apart therefrom by a predetermined interval in the circumferential direction. Further, the fourth height H4 may be formed to be larger than the third height H3 by a predetermined degree, and the height of the outer rail 130 may gradually increase in the circumferential direction from the position of the third height H3 to the position of the fourth height H4, and in a reverse case, the height of the outer rail 130 may gradually decrease.

When the concept is differently described, the 2-2^{nd} bearing groove 131 and the 3-1^{st} bearing groove 132 may be vertically spaced apart from each other by a third interval G3 at one side (the left side in the drawing) of the outer rail 130, and the 2-2^{nd} bearing groove 131 and the 3-1^{st} bearing groove 132 may be vertically spaced apart from each other by a fourth interval G4 at the other side (the right side in the drawing) of the outer rail 130. The third interval G3 and the fourth interval G4 may be defined as an interval between an upper and lower-direction center of the 2-2^{nd} bearing groove 131 and an upper and lower-direction center of the 3-1^{st} bearing groove 132. Here, the fourth interval G4 may be formed to be larger than the third interval G3 by a predetermined degree. Further, the interval between the 2-2^{nd} bearing groove 131c and the 3-1^{st} bearing groove 132 may gradually increase in the circumferential direction from the position of the third interval G3 to the position of the fourth interval G4, and in contrast, the interval between the 2-2^{nd} bearing groove 131 and the 3-1^{st} bearing groove 132 may gradually decrease in the circumferential direction from the position of the fourth interval G4 to the position of the third interval G3.

In the above description, the third and fourth heights H3 and H4 or the third and fourth intervals G3 and G4 may be equal to or different from the first and second heights H1 and H2 or the first and second intervals G1 and G2. That is, the third and fourth heights H3 and H4 or the third and fourth intervals G3 and G4 of the outer rail 130 may not be equal to the first and second heights H1 and H2 or the first and second intervals G1 and G2.

A height difference between the inner rail 120 and the outer rail 130, or an interval difference of each of the bearings 112a, 123, 124, 131, and 132 may cause a difference between the interval between the first bearing 161 and the second bearing 162, and the interval between the second bearing 162 and the third bearing 163. That is, the interval between the first bearing 161 and the second bearing 162 spaced apart from each other vertically may be shown differently according to each position in the circumferential direction. Further, the interval between the second bearing 162 and the third bearing 163 spaced apart from each other vertically may be shown differently according to each position in the circumferential direction. In other words, the interval between the first bearing 161 and the second bearing 162 or the interval between the second bearing 162 and the third bearing 163 may gradually increase or decrease to correspond to the interval of the bearings 112a, 123, 124, 131, and 132.

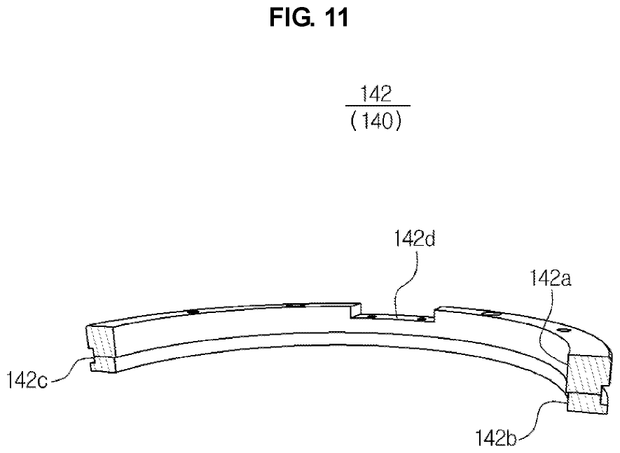

FIG. 11 is a schematic longitudinal cross-sectional view separately illustrating an upper base illustrated in FIG. 4.

Referring to FIG. 11, the upper base 140 may include the upper rail 142. For reference, the upper plate may be fastened to the top of the upper rail 142. The upper rail 142 may be extended in the circular shape with a predetermined radius. The upper rail is fastened to the lower plate 111 through the elastic clip to be restrained from being rotated. That is, the inner rail 120 and the outer rail 130 are rotatable, while the upper rail 142 may be restrained from being rotated by the elastic clip 151. However, the upper rail 142 may be tilted to the lower plate by a predetermined degree according to the rotation position of the outer rail 130.

Similar to the lower rail 112, the upper rail 112 may be split into a plurality of upper rails as necessary. In the embodiment, a case where the upper rail 142 is split into an upper rail upper block 142a and an upper rail lower block 142b is exemplified.

Further, the upper rail 142 may include a 3-2^{nd} bearing groove 142c. The 3-2^{nd} bearing groove 142c may be extended along the radial outer surface of the upper rail 142. The 3-2^{nd} bearing groove 142c is combined with the 3-1^{st} bearing groove 132 to mount and support the third bearing 163.

According to the above description, the upper rail 142 may be supported on the outer rail 130. That is, the third bearing 163 is fastened to the 3-1^{st} bearing groove 132 formed in the outer rail 130, and the 3-2^{nd} bearing groove 142c formed in the upper rail 142 is fastened to the third bearing 163 again, so the upper rail 142 may be supported on the outer rail 130 via the third bearing 163. However, as described above, the upper rail 142 may be restrained from being rotated by the elastic clip 151.

A clip fastening part 142d may be provided in the upper rail 142 as necessary. The elastic clip 151 supporting a gap between the upper rail 142 and the lower plate 111 may be fastened to the clip fastening part 142d. The clip fastening part 142d may be formed at one circumferential side of the upper rail 142, and formed with the upper surface of the upper rail 142 being stepped downward and inserted into a lower side thereof.

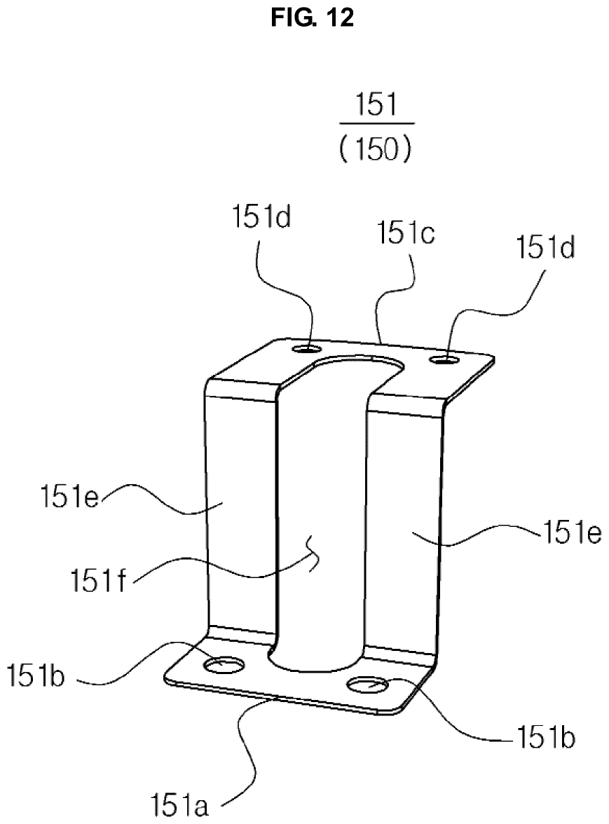

FIG. 12 is a schematic longitudinal perspective view separately illustrating a rotation support part illustrated in FIG. 4.

FIG. 12 illustrates the elastic clip 151 as an embodiment of the rotation support part 150. An upper end of the elastic clip 151 may be fastened to the clip fastening part 142d provided in the upper rail 142, and a lower end may be fastened to the lower plate 111. As a result, the upper rail 142 may be fixed to the lower plate 111 and restrained from being rotated in spite of the rotation of the inner rail 120 and the outer rail 130.

A part or the entirety of the elastic clip 151 may be made of an elastic material which is elastically transformable. As a result, the upper rail 142 may be tilted to the lower plate 111. That is, while the elastic clip 151 is elastically transformed according to the rotation positions of the inner rail 120 and the outer rail 130, the upper rail 142 is tilted.

Specifically, the elastic clip 151 may include a first end 151a fastened to the lower plate 111. The first end 151a may be extended in a substantially transverse direction, and may include a first fixation hole 151b to be fastened to the lower plate 111. Preferably, a pair of first fixation holes 151b may be provided, which are spaced apart from each other to the left and right to correspond to left and right extension pieces 151e to be described below.

Further, the elastic clip 151 may include a second end 151c fastened to the upper rail 142. Similar to the first end 151a, the second end 151c may be extended in the substantially transverse direction, and may include a second fixation hole 151d to be fastened to the upper rail 142. The second end 151c may be fastened to the clip fastening part 142d formed in the upper rail 142. Further, similar to the first end 151a, a pair of second fixation holes 151d may be provided, which are spaced apart from each other to the left and right to correspond to the left and right extension pieces 151e to be described below.

Further, the elastic clip 151 may include an extension piece 151e extended between the first end 151a and the second end 151c. The extension piece 151e may be extended in the upper and lower directions between the first end 151a at the lower side and the second end 151c at the upper side.

Here, an induction hole 151f may penetrate a center of the extension piece 151e. As a result, the extension piece 151e may be divided into left and right pieces with the induction hole 151f interposed therebetween. Further, the induction hole 151f may be extended upwards from a partial area of the first end 151a along the extension piece 151e, and extended to reach a partial area of the second end 151c. As a result, the first fixation hole 151b at the lower end, one side of the extension piece 151e, and the second fixation hole 151d at the upper end may be disposed substantially on one extension line at one side (the left side in the drawing) of the elastic clip 151, and the first fixation hole 151b at the lower end, the opposite side of the extension piece 151e, and the second fixation hole 151d at the upper end may be disposed substantially on one extension line even at the opposite side (the right side in the drawing) of the elastic clip 151.

The elastic clip 151 may appropriately elastically support the tilting between the lower plate 111 and the upper rail 142 by the shape and the fastening structure. That is, the extension piece 151e is divided into the left and right pieces through the induction hole 151f, so the extension piece 151e may be more freely elastically transformed according to the tilting angle, and the induction hole 151f may provide a spare space for elastic transformation of the extension piece 151e.

FIG. 13 is a schematic perspective view illustrating another embodiment of a rotation support part illustrated in FIG. 12.

FIG. 13 illustrates a hinge pin 251 as an embodiment of the rotation support part 251. The hinge pin 251 of the embodiment may replace the elastic clip 151 in terms of a function. That is, an upper end of the hinge pin 251 is fastened to the upper plate 141 and a lower end is fastened to the lower plate 111 to restrain the upper plate 141 from being rotated with respect to the lower plate 111.

Specifically, the hinge pin 251 may include an upper pin 251a. The upper pin 251a may be extended in the longitudinal direction, and inserted and fastened into the upper plate 141. However, the upper pin 251a may be formed not to restrain the upper plate 141 being rotated with the upper pin 251a as an axis. As a result, the upper plate 141 may be tilted with the upper pin 251a as the axis.

Further, the hinge pin 251 may include an upper hinge block 251b. The upper hinge block 251b may be hinge-coupled to one end of the upper pin 251a around a first hinge axis R1. Here, the first hinge axis R1 may be disposed to be perpendicular to the longitudinal direction of the upper pin 251a. As a result, the upper plate 141 may be tilted around the first hinge axis R1.

Further, the hinge pin 251 may include a lower hinge block 251c. The lower hinge block 251c may be hinge-coupled to a lower end of the upper hinge block 251b around a second hinge axis R2. The second hinge axis R2 is spaced apart from a lower side of the first hinge axis R1 by a predetermined interval to be disposed in a direction to correspond to the first hinge axis R1. As a result, the upper plate 141 may be tilted around the second hinge axis R2.

Further, the hinge pin 251 may include a lower pin 251d. The lower pin 251d may be hinge-coupled to a lower end of the lower hinge block 251c around a third hinge axis R3. The third hinge axis R3 is spaced apart from a lower side of the second hinge axis R2 by a predetermined interval to be disposed in a direction to correspond to the second hinge axis R2. As a result, the upper plate 141 may be tilted around the third hinge axis R3.

The lower pin 251d may be extended in the longitudinal direction, and inserted and fastened into the lower plate 111. Similar to the upper pin 251a, the lower pin 251d may be not be restrained from being rotated with respect to the lower plate 111. As a result, the upper plate 141 may be tilted with the lower pin 251d as the axis.

The hinge pin 251 may allow the upper plate 141 to be appropriately tilted with respect to the lower plate 111 along the upper pin 251a and the lower pin 251d, and the first to third hinge axes R1 to R3, and may perform a similar function by replacing the elastic clip 151.

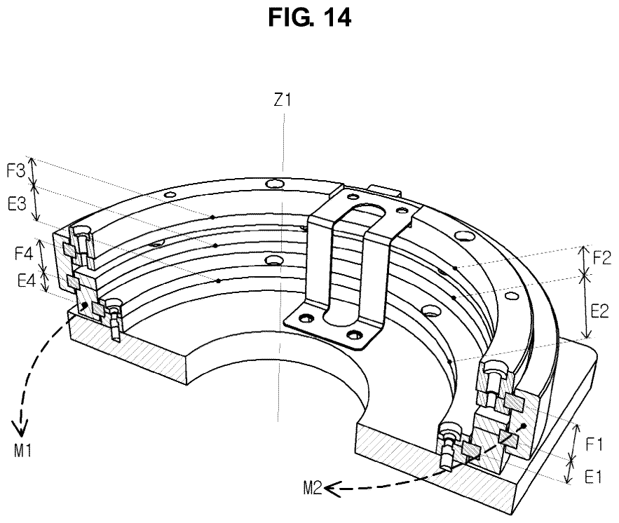

FIG. 14 is an operation diagram of the balance stage illustrated in FIG. 4.

Referring to FIG. 14, in the balance stage 100 of the embodiment, the placement angle of the upper rail 142 may be adjusted according to the rotation positions of the inner rail 120 and the outer rail 130. Further, the object is disposed in the upper rail 142 via the upper plate 141, so a placement angle of the object may be appropriately adjusted.

Specifically, based on the illustration in FIG. 14, at a right end, an interval between the first bearing 161 and the second bearing 162 is E1 and an interval between the second bearing 162 and the third bearing 163 is E2. For reference, the interval between the first bearing 161 and the second bearing 162 corresponds to the interval between the 1-2^{nd} bearing groove 121c and the 2-1^{st} bearing groove 124 (see FIG. 9), and the interval between the second bearing 162 and the third bearing 163 corresponds to the interval between the 2-2^{nd} bearing groove 131 and the 3-1^{st} bearing groove 132 (see FIG. 10). In such a case, an interval between the lower rail 112 (i.e., corresponding to the first bearing) and the upper rail 142 (i.e., corresponding to the third bearing 163) may be formed as “E1+F1”.

Similar thereto, at a position spaced apart from a position of E1 by a predetermined interval in the circumferential direction, the interval between the first bearing 161 and the second bearing 162 may be formed as E2, and the interval between the second bearing 162 and the third bearing 163 may be formed as F2. Further, here, at a position spaced apart by a predetermined interval in the circumferential direction again, the interval between the first bearing 161 and the second bearing 162 may be formed as E3, and the interval between the second bearing 162 and the third bearing 163 may be formed F3, and here, at an opposite side to a position of E1 spaced apart by a predetermined interval in the circumferential direction again, the interval between the first bearing 161 and the second bearing 162 may be formed as E4, and the interval between the second bearing 162 and the third bearing 163 may be formed F4. At each position, the interval between the lower rail 112 and the upper rail 142 may be formed as “E2+F2” similarly as described above.

Here, in the balance stage 100 of the embodiment, according to the position in the circumferential direction, the interval between the first bearing 161 and the second bearing 162 may be differently formed, and the interval between the second bearing 162 and the third bearing 163 may also be formed differently. As a result, “E1+F1” to “E4+F4” may be formed differently. For example, “E1+F1” is largest, and as the interval decreases in the circumferential direction, so “E4+F4” may be disposed to be smallest. In such a case, the upper rail 142 or the object may be disposed to be tilted to a position corresponding to E4.

Meanwhile, the tilting direction may be adjusted by rotation of the inner rail 120 and the outer rail 130. For example, when the inner rail 120 and the outer rail 130 are jointly rotated in the illustrated state, and the position corresponding to E4 is thus moved clockwise, the tilting direction may also be moved clockwise in response thereto. The balance stage 100 may easily adjust the tilting direction by such a scheme. Further, the tilting direction may be adjusted by the rotation positions of the inner rail 120 and the outer rail 130.

Meanwhile, the tilting angle direction may be adjusted by rotation of the inner rail 120 or the outer rail 130. More specifically, the tilting angle may be adjusted by the interval between the first bearing 161 and the second bearing 162 according to the rotation position of the inner rail 120 or the interval between the second bearing 162 and the third bearing 163 according to the rotation position of the outer rail 130. For example, it is assumed that in the illustrated state, only the inner rail 120 is rotated at a predetermined angle clockwise, so a position corresponding to E2 is rotated up to a position corresponding to E1. In such a case, at the illustrated right end, the interval between the first bearing 161 and the second bearing 162 may be changed from initial E1 to E2 according to the rotation of the inner rail 120. The interval between the first bearing 161 and the second bearing 162 may be reduced. On the contrary, since the outer rail 130 is not rotated, the interval between the second bearing 162 and the third bearing 163 may be maintained as F1. Finally, the interval between the lower rail 112 and the upper rail 142 at the right end is changed to “E2+F1”, the placement angles of the upper rail 142 to the object may be changed.

Further, by the similar scheme, the rotation position of the inner rail 120 or the outer rail 130 is changed or the rotation position of the inner rail 120 or the outer rail 130 is changed as necessary to implement various tilting angles. Here, since the change of the tilting angle is implemented by the interval between the first bearing 161 and the second bearing 162 or the interval between the second bearing 162 and the third bearing 163 formed to be gradually changed, the tilting angle may be significantly precisely adjusted in spite of a simple manipulation scheme.

As described above, the balance stage 100 according to the embodiments of the present invention can adjust a tilting direction or angle of an object, and implement an tilting operation through rotation of the inner rail 120 or the outer rail 130.

Here, the balance stage 100 according to the embodiments of the present invention has a structure in which the tilting direction or angle is adjusted through tilting of the inner rail 120 or outer rail 130, and a rotation position of the inner rail or outer rail, a simple structure is provided and precise angle control is possible compared to the related art. Further, there is an advantage in that manufacturing or handling is easy according to a simple or intuitive structure.

Further, the balance stage 100 according to the embodiments of the present invention has a structure in which the inner rail 120, the outer rail 130, and the upper base 140 are supported throughout an entire area in the circumferential direction based on the lower base 110. Accordingly, the balance stage can have a very stable weight support structure, and can be appropriately used even with respect to the object with a large weight. Furthermore, durability is excellent according to the stable weight support structure, and malfunction can also be significantly reduced.

Further, embodiments of the present invention have been explained and described, but it will be appreciated by those skilled in the art that the present invention may be modified and changed in various ways without departing from the spirit of the present invention described in the claims by the addition, change, deletion or addition of constituent elements, and that the modifications and changes are included in the claims of the present invention.

1. A balance stage comprising:
a lower base 110 disposed on an installation surface;
an inner rail 120 extended in a circumferential direction, and supported on the lower base 110 to be rotatable with respect to the lower base 110 around a central axis Z1 in the circumferential direction;
an outer rail 120 extended in the circumferential direction, and supported on the inner rail 120 to be rotatable with respect to the inner rail 120 around the central axis Z1;
an upper base 140 which is supported on the outer rail 130, and in which an object is disposed; and
a rotation support part 150 fastened between the lower base 110 and the upper base 140, and restraining rotation of the upper base 140 with respect to the lower base 110.

2. The balance stage of claim 1, wherein the inner rail 120 is rotatably fastened to the lower base 110 via a first bearing 161, and rotatably fastened to the outer rail 130 via a second bearing 162 spaced apart from an upper side of the first bearing 161 by a predetermined interval, and
the first bearing 161 and the second bearing 162 are disposed to have a first interval G1 vertically at one side in the circumferential direction of the inner rail 120, and a second interval G2 different from the first interval G1 vertically at the other side spaced apart from one side by a predetermined interval.

3. The balance stage of claim 2, wherein the first bearing 161 and the second bearing 162 are formed with a vertical spacing interval gradually increases or decreases from one side in the circumferential direction of the inner rail 120 corresponding to the first interval G1 to the other side corresponding to the second interval G2 in the circumferential direction.

4. The balance stage of claim 2, wherein the outer rail 130 is rotatably fastened to the inner rail 120 via a third bearing 163 disposed to be spaced apart from an upper side of the second bearing 162 by a predetermined interval, and
the second bearing 162 and the third bearing 163 are disposed to have a third interval G3 vertically at one side in the circumferential direction of the outer rail 130, and a fourth interval G4 different from the third interval G3 vertically at the other side spaced apart from one side by a predetermined interval.

5. The balance stage of claim 4, wherein the second bearing 162 and the third bearing 163 are formed with a vertical spacing interval gradually increases or decreases from one side in the circumferential direction of the outer rail 130 corresponding to the third interval G3 to the other side corresponding to the fourth interval G4 in the circumferential direction.

6. The balance stage of claim 4, wherein the inner rail 120 and the outer rail 130 are formed to be rotated independently from each other and disposed at predetermined rotation positions, and
the upper base 140 is formed to be tilted in a predetermined direction and at a predetermined angle according to the rotation positions of the inner rail 120 and the outer rail 130 while the being restrained from being rotated by the rotation support part 150.

7. The balance stage of claim 1, wherein the rotation support part 150 includes an elastic clip 151 of which a part or the entirety is made of an elastic material to allow tilting of the upper base 140 with respect to the lower base 110.

8. The balance stage of claim 7, wherein the elastic clip 151 includes
a first end 151a including a pair of first fixation holes 151b spaced to the left and right, and fixed to the lower base 110,
a second end 151c disposed to be spaced upwards from the first end 151a, including a pair of second fixation holes 151d spaced to the left and right, and fixed to the lower base 110, and
an extension piece 151e extended between the first end 151a and the second end 151c, and extended in upper and lower directions to induce elastic transformation.
